(19) United States
(12) Patent Application Publication
(10) Pub. No.: US 2020/0315017 A1
(43) Pub. Date: Oct. 1, 2020

(54) SEMICONDUCTOR PACKAGE

(71) Applicant: Powerchip Semiconductor Manufacturing Corporation, Hsinchu (TW)

(72) Inventors: Chun-Liang Chen, Hsinchu County (TW); Hann-Jye Hsu, Hsinchu City (TW)

(73) Assignee: Powerchip Semiconductor Manufacturing Corporation, Hsinchu (TW)

(21) Appl. No.: 16/507,050

(22) Filed: Jul. 10, 2019

(30) Foreign Application Priority Data
Mar. 27, 2019 (TW) 108110759

(51) Int. Cl. H05K 1/18; H01L 27/32; H01L 23/00; H01L 23/538; G02F 1/1345; G09G 3/20

(52) U.S. Cl. CPC H05K 1/189; H05K 1/118; H01L 24/32; H01L 23/5387; G02F 1/13452; G09G 3/2092; H01L 2224/32227; H01L 2924/1426; H01L 2924/1437; H01L 2924/1438; H01L 2924/14511; H05K 2201/10136; H05K 2201/10159; H05K 2201/056; H01L 27/3276

(57) ABSTRACT

The present disclosure provides a semiconductor package including a substrate, a display unit, a flexible circuit board, a driving circuit, and a memory. The substrate has a first surface and a second surface opposite to each other, and the first surface has a display region and a bonding region. The display unit is disposed on the display region of the first surface. The flexible circuit board is disposed below the second surface and has a connection portion extended to the bonding region of the first surface. The driving circuit is disposed on the flexible circuit board and electrically connects to the display unit. The memory is disposed on the flexible circuit board and electrically connects to the driving circuit.

### CROSS-REFERENCE TO RELATED APPLICATION

This application claims the priority benefit of Taiwan application serial no. 108110759, filed on Mar. 27, 2019. The entirety of the above-mentioned patent application is hereby incorporated by reference herein and made a part of this specification.

### BACKGROUND OF THE INVENTION

### 1. Field of the Invention

The invention relates to a package structure, and more particularly, to a semiconductor package. cl 2. Description of Related Art

With the development of display technology, the demand for a driver with high-integration IC that capable of driving a display unit after connection (also referred to as a driver IC) is increased, and thus various semiconductor packages have been developed. In general, a common semiconductor package for driving the display unit may be, for example, a chip on glass (COG), a tape carrier package (TCP), or a chip on film (COF). The TCP and COF can make the display to have a narrow border design compared to the COG, so it is commonly used to the semiconductor package for driving the display unit. However, as the demand for the drivers to have small size and/or high operation speeds is increased, the TCP has been gradually replaced by the COF due to its circuit pitch and bonding pitch being inferior to the COF.

Recently, as the users demand higher display quality (e.g. image resolution, color saturation, and the like), the data to be processed by the driver is increased, therefore, a defect (e.g. mura) may be occurred caused by the image delay due to the time required to process the data is too long.

### SUMMARY OF THE INVENTION

The invention provides a semiconductor package that can have high operation speed, low power consumption, and good process flexibility.

An embodiment of the invention provides a semiconductor package including a substrate, a display unit, a flexible circuit board, a driving circuit, and a memory. The substrate has a first surface and a second surface opposite to each other, and the first surface has a display region and a bonding region. The display unit is disposed on the display region of the first surface. The flexible circuit board is disposed below the second surface and has a connection portion extended to the bonding region of the first surface. The driving circuit is disposed on the flexible circuit board and electrically connects to the display unit. The memory is disposed on the flexible circuit board and electrically connects to the driving circuit.

According to an embodiment of the invention, in the semiconductor package, the driving circuit and the memory are spaced apart from each other.

According to an embodiment of the invention, in the semiconductor package, the memory is electrically connected to the driving circuit through the flexible circuit board.

According to an embodiment of the invention, in the semiconductor package, the memory is disposed on the driving circuit.

According to an embodiment of the invention, in the semiconductor package, the display unit overlaps with the driving circuit and the memory in a vertical projection direction of the substrate.

According to an embodiment of the invention, in the semiconductor package, the connection portion includes a connection pad, and the connection pad is electrically connected to a pad in the bonding region.

According to an embodiment of the invention, the semiconductor package further includes a conductive layer disposed between the connection pad and the pad.

According to an embodiment of the invention, in the semiconductor package, the driving circuit includes a source driving circuit.

According to an embodiment of the invention, in the semiconductor package, the memory includes a static random access memory (SRAM), a flash memory, an electrically erasable and programmable read only memory (EEPROM), or a combination thereof.

According to an embodiment of the invention, in the semiconductor package, the display unit comprises a liquid crystal display (LCD) or an organic light emitting diode (OLED).

Based on the above, the memory and the driving circuit of the semiconductor package of the present invention are electrically connected to each other and disposed on the flexible circuit board, so that the driving circuit can handle a large amount of image data. As a result, the semiconductor package may have characteristics of high operation speed and low power consumption so as to meet the frame rate requirement of the display unit having high resolution and high quality.

On the other hand, since the driving circuit and the memory may be separately manufactured through different processes, and then respectively disposed on the flexible circuit board, the semiconductor package may have good process flexibility in the case where the processes of the driving circuit and the memory are separated.

To make the above features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a cross-sectional view of the semiconductor package in an embodiment of the invention.

FIG. 2 is a schematic diagram illustrating the signal connection of the driving circuit, memory, and display unit of the semiconductor package in an embodiment of the invention.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The invention will be described more comprehensively below with reference to the drawings for the embodiments. However, the invention may also be implemented in different forms rather than being limited by the embodiments described in the invention. Thicknesses of layer and region in the drawings are enlarged for clarity. The same reference numbers are used in the drawings and the description to indicate the same or like parts, which are not repeated in the following embodiments.

It will be understood that when an element is referred to as being “on” or “connected” to another element, it may be directly on or connected to the other element or intervening elements may be present. If an element is referred to as being “directly on” or “directly connected” to another element, there are no intervening elements present. As used herein, “connection” may refer to both physical and/or electrical connections, and “electrical connection” or “coupling” may refer to the presence of other elements between two elements.

As used herein, “about”, “approximately” or “substantially” includes the values as mentioned and the average values within the range of acceptable deviations that can be determined by those of ordinary skill in the art. Consider to the specific amount of errors related to the measurements (i.e., the limitations of the measurement system), the meaning of “about” may be, for example, referred to a value within one or more standard deviations of the value, or within ±30%, ±20%, ±10%, ±5%. Furthermore, the “about”, “approximate” or “substantially” used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

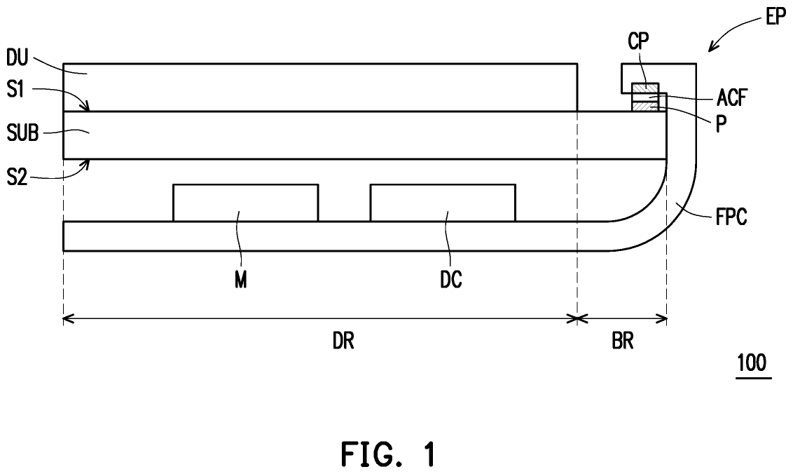

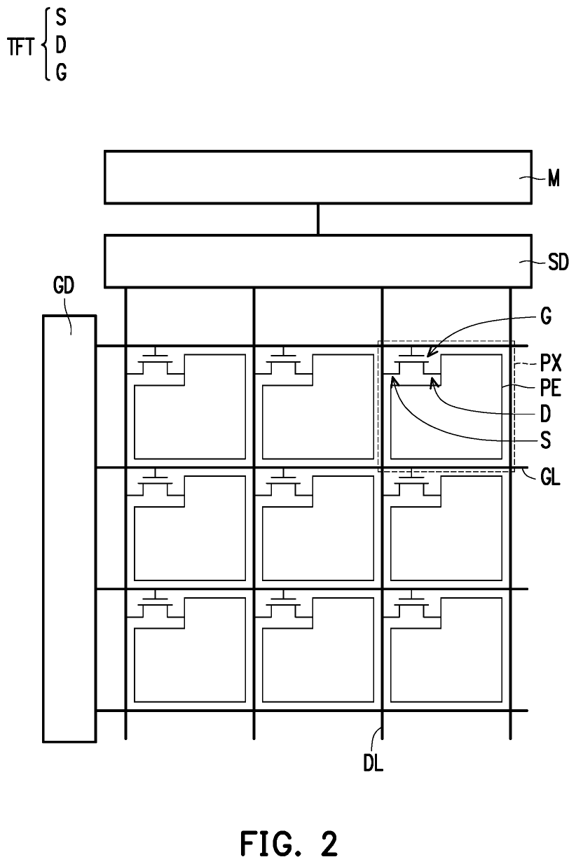

FIG. 1 is a cross-sectional view of the semiconductor package in an embodiment of the invention. FIG. 2 is a schematic diagram illustrating the signal connection of the driving circuit, memory, and display unit of the semiconductor package in an embodiment of the invention.

Referring to FIG. 1, a semiconductor package 100 includes a substrate SUB, a display unit DU, a flexible circuit board FPC, a driving circuit DC, and a memory M.

The substrate SUB has a first surface S1 and a second surface S2 opposite to each other, and the first surface S1 has a display region DR and a bonding region BR. The substrate SUB may be a rigid substrate or a flexible substrate. For instance, the substrate SUB may be glass, quartz, organic polymer, or other suitable materials.

Referring to both FIG. 1 and FIG. 2, the display unit DU is disposed on the display region DR of the first surface S1. In the present embodiment, the display unit DU may include a liquid crystal display (LCD) or an organic light emitting diode (OLED). In the present embodiment, the display unit DU is described as an exemplary embodiment of the liquid crystal display, but the invention is not limited thereto. For instance, the display unit DU may include a plurality of sub-pixels PX arranged on the substrate SUB in an array and a plurality of signal lines GL, DL interlaced with each other. In the present embodiment, each of the sub-pixels PX may include an active element TFT and a pixel electrode PE. The active element TFT may include a gate G, a source S, and a drain D, wherein the gate G may be electrically connected to the corresponding signal line GL (e.g., a gate line); and the source S may be electrically connected to the corresponding signal line DL (e.g., a data line); and the drain D may be electrically connected to the corresponding pixel electrode PE. The active element TFT may be a bottom-gate type transistor, a top-gate type transistor, or other suitable transistor. In some embodiments, the pixel electrode PE may optionally include a plurality of slits (not shown) having different extending directions or a plurality of slits having substantially the same extending direction, but the invention is not limited thereto.

The flexible circuit board FPC is disposed below the second surface S2 (In other words, the flexible circuit board FPC is disposed on the second surface S2) and has a connection portion EP extending to the bonding region BR of the first surface S1. The material of the flexible circuit board FPC may include polyimide (PI). In the present embodiment, the connection portion EP may include a connection pad CP. The connection pad CP is electrically connected to a pad P in the bonding region BR; and the pad P is electrically connected to the active element TFT in the display unit DU. For instance, the pad P may be electrically connected to the source S of the active element TFT. The material of the connection pad CP may be a conductive material such as a metal, a metal oxide, or a combination thereof. The material of the pad P may be a conductive material such as a metal, a metal oxide, or a combination thereof.

In some embodiments, the semiconductor package 100 may optionally include a conductive layer ACF. The conductive layer ACF is disposed between the connection pad CP and the pad P, so that the connection pad CP may be electrically connected to the pad P through the conductive layer ACF. The conductive layer ACF may be a conductive bump, a conductive paste, a solder, or a combination thereof. For example, the conductive layer ACF may be an anisotropic conductive film (ACF).

The driving circuit DC is disposed on the flexible circuit board FPC and electrically connected to the display unit DU, and the memory M is disposed on the flexible circuit board FPC and electrically connected to the driving circuit DC. In this way, the memory M may temporarily store the image data as a frame buffer, so that the driving circuit DC (e.g., the source driving circuit SD) may handle a large amount of image data from a micro control unit (MCU) or a micro control unit integrated dynamic random access memory (MCU/DRAM). As a result, the semiconductor package 100 may have characteristics of high operation speed and low power consumption so as to meet the frame rate requirement of the display unit DU having high resolution and high quality. In the present embodiment, the driving circuit DC and the memory M may be spaced apart from each other. In some embodiments, the memory M may be disposed on the driving circuit DC. The driving circuit DC may include a source driving circuit SD. The source driving circuit SD may be electrically connected to the source S of the active element TFT through the signal line DL. In some embodiments, the semiconductor package 100 may further include a gate driving circuit GD. The gate driving circuit GD may be electrically connected to the gate G of the active element TFT through the signal line GL. The memory M may include a static random access memory (SRAM), a flash memory (Flash), an electronic erasable programmable read only memory (EEPROM), or a combination thereof.

On the other hand, since the memory M and the driving circuit DC are both disposed on the flexible circuit board FPC, additional bus lines for connecting the driving circuit DC to the external memory element is not required. As a result, the transmission speed of image data is enhanced and the process for manufacturing the semiconductor package is simplified. For example, the memory M is electrically connected to the driving circuit DC through the flexible circuit board FPC.

In addition, the driving circuit DC is a kind of high-voltage semiconductor elements; and the operating voltage of the memory M is similar to the voltage of the general logic circuit, so the driving circuit DC and the memory M may have different limitations in the process design requirements. Therefore, the integration of these two processes may have a certain degree of difficulty. In the present embodiment, the driving circuit DC and the memory M may be separately manufactured through different processes, and then respectively disposed on the flexible circuit board. In this way, the semiconductor package may have good process flexibility in the case where the processes of the driving circuit DC and the memory M may be separated. Moreover, the driving circuit DC and memory M may also have good process flexibility in manufacturing.

In some embodiments, the narrow border design may be achieved by disposing the driving circuit DC and the memory M on the flexible circuit board FPC located on the rear side of the substrate SUB (i.e., the second surface S2). In other words, in the vertical projection direction of the substrate SUB, the display unit DU may overlap with the driving circuit DC and the memory M.

In summary, the memory and the driving circuit of the semiconductor package of the present embodiment are electrically connected to each other and disposed on the flexible circuit board, so that the driving circuit is capable of handling a large amount of image data. As a result, the semiconductor package may have characteristics of high operation speed and low power consumption so as to meet the frame rate requirement of the display unit having high resolution and high quality.

On the other hand, since the driving circuit and the memory may be separately manufactured through different processes, and then respectively disposed on the flexible circuit board, the semiconductor package may have good process flexibility in the case where the processes of the driving circuit and the memory are separated.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor package, comprising:
a substrate, having a first surface and a second surface opposite to each other, and the first surface has a display region and a bonding region;
a display unit, disposed on the display region of the first surface;
a flexible circuit board, disposed below the second surface and having a connection portion extended to the bonding region of the first surface;
a driving circuit, disposed on the flexible circuit board and electrically connected to the display unit; and
a memory, disposed on the flexible circuit board and electrically connected to the driving circuit.

2. The semiconductor package according to claim 1, wherein the driving circuit and the memory are spaced apart from each other.

3. The semiconductor package to claim 2, wherein the memory is electrically connected to the driving circuit through the flexible circuit board.

4. The semiconductor package according to claim 1, wherein the memory is disposed on the driving circuit.

5. The semiconductor package according to claim 1, wherein the display unit overlaps with the driving circuit and the memory in a vertical projection direction of the substrate.

6. The semiconductor package according to claim 1, wherein the connection portion comprises a connection pad, and the connection pad is electrically connected to a pad in the bonding region.

7. The semiconductor package according to claim 6, further comprising:
a conductive layer, disposed between the connection pad and the pad.

8. The semiconductor package according to claim 1, wherein the driving circuit comprises a source driving circuit.

9. The semiconductor package according to claim 1, wherein the memory comprises a static random access memory (SRAM), a flash memory, an electrically erasable and programmable read only memory (EEPROM), or a combination thereof.

10. The semiconductor package according to claim 1, wherein the display unit comprises a liquid crystal display (LCD) or an organic light emitting diode (OLED).
